(19) United States
(12) Patent Application Publication
(10) Pub. No.: US 2016/0293887 A1
(43) Pub. Date: Oct. 6, 2016

(54) ORGANIC LIGHT-EMITTING DEVICE AND METHOD OF MANUFACTURING THE SAME, AND DISPLAY HAVING THE DEVICE

(71) Applicants: BOE TECHNOLOGY GROUP CO., LTD., Beijing (CN); HEFEI XINSHENG OPTOELECTRONICS TECHNOLOGY CO., LTD, Hefei, Anhui (CN)

(72) Inventor: Peng Chen, Beijing (CN)

(73) Assignees: BOE Technology Group Co., Ltd., Beijing (CN); Hefei Xinsheng Optoelectronics Technology Co., Ltd., Anhui (CN)

(21) Appl. No.: 14/777,799

(22) PCT Filed: Jan. 29, 2015
(86) PCT No.: PCT/CN2015/071811

§ 371 Date: Sep. 17, 2015

(30) Foreign Application Priority Data
Sep. 30, 2014 (CN) 201410522062.9

(51) Int. Cl. H01L 51/52; H01L 51/50; H01L 51/56

(52) U.S. Cl. CPC H01L 51/5256; H01L 51/56; H01L 51/5218; H01L 51/5056; H01L 51/5092; H01L 51/5072

(57) ABSTRACT

The embodiments of the present invention disclose an organic light-emitting device. The organic light-emitting device includes a substrate, a cathode layer, an organic light-emitting layer, a metal layer and an anode layer which are arranged in sequence from below upwards. The metal layer is formed between the organic light-emitting layer and the anode layer. Meanwhile, the embodiments of the present invention also discloses a method of manufacturing an organic light-emitting device. In addition, the embodiments of the present invention further discloses a display with the abovementioned organic light-emitting device. In the present invention, a micro resonant cavity is combined with a structural design of an inverted device thereby to effectively prolong service life of the organic light-emitting device, decrease a turn-on voltage of the organic light-emitting device, and improve color purity and intensity.

### CROSS-REFERENCE TO RELATED APPLICATIONS

This application is a Section 371 National Stage Application of International Application No. PCT/CN2015/071811, filed 29 Jan. 2015, entitled “ORGANIC LIGHT-EMITTING DEVICE AND METHOD OF MANUFACTURING THE SAME, AND DISPLAY HAVING THE DEVICE”, which has not yet published, which claims priority to Chinese Application No. 201410522062.9, filed on 30 Sep. 2014, incorporated herein by reference in their entirety.

### BACKGROUND

1. Technical Field

Embodiments of the present invention relates to the field of organic light emitting, and particularly, to an inverted organic light-emitting device (OLED) and a method of manufacturing the same, and a display having the device.

2. Description of the Related Art

The OLED has a typical sandwich structure. Since material of an organic layer is sensitive to water and oxygen, service life of the OLED will decrease sharply after the OLED contacts with water and oxygen. How to prolong the service life of the OLED is a difficulty with which manufacturers is confronted at present.

In order to isolate the device from water and oxygen, methods of improving tightness of packaging glass may be used. For example, a method in which a substrate glass and a cover plate glass are sealed by UV sealing adhesive is replaced with a method in which they are sealed by melting glass powder, or with manners such as that in which a groove is formed on the cover plate glass and drying agent tablets are placed in the groove. However, among these methods, some require expensive special equipment such as laser equipment for melting glass power and have long process time, while others require that the cover plate glass be further machined so that glass having a small thickness cannot be used and thus requirements that a flat panel display apparatus should be light and thin cannot be achieved.

### SUMMARY

Embodiments of the present invention provide an organic light-emitting device which may comprise a substrate, a cathode layer, an organic light-emitting layer, a metal layer and an anode layer which are arranged in sequence from below upwards, wherein:

the metal layer is formed between the organic light-emitting layer and the anode layer.

Specifically, the organic light-emitting device further comprises a passivation layer between the metal layer and the anode layer, and the passivation layer is formed by oxidizing a part of the metal layer when the anode layer is formed.

According to embodiments of the present invention, the metal layer is an aluminum layer, and the passivation layer is a passivation layer of Al₂O₃.

According to embodiments of the present invention, the metal layer may have a thickness of 10-15 nm. According to embodiments of the present invention, the metal layer is an optically semi-transmissive layer and forms a micro resonant cavity together with the cathode layer.

According to embodiments of the present invention, the organic light-emitting device further comprises an electron injection and transport layer arranged between the cathode layer and the organic light-emitting layer. In some embodiments, the electron injection and transport layer has functions of both injection and transport of electrons. In some other embodiments, the electron injection and transport layer may further comprise an electron injection sublayer and an electron transport sublayer.

According to embodiments of the present invention, the organic light-emitting device further comprises a hole transport and injection layer arranged between the organic light-emitting layer and the metal layer. In some embodiments, the hole transport and injection layer has functions of both injection and transport of holes. In some other embodiments, the hole transport and injection layer may further comprise a hole injection sublayer and a hole transport sublayer.

According to embodiments of the present invention, the electron injection and transport layer and the organic light-emitting layer are made of material having a low work function, while the hole transport and injection layer is made of material having a high work function.

According to embodiments of the present invention, the cathode layer may be made of a lithium-aluminum alloy, and has a thickness of 200-300 nm

According to embodiments of the present invention, the anode layer may be made of indium tin oxide (ITO).

According to embodiments of the present invention, the organic light-emitting device is a top-emitting device.

Embodiments of the present invention provide a method of manufacturing an organic light-emitting device comprising at least:

step 1 of forming a cathode layer on a substrate;

step 2 of forming an organic light-emitting layer on the cathode layer;

step 3 of forming a metal layer on the organic light-emitting layer; and

step 4 of forming an anode layer on the metal layer.

Specifically, in the abovementioned step 4 of forming the anode layer, while the anode layer is formed, a part of the metal layer is oxidized to form a passivation layer.

According to embodiments of the present invention, the metal layer is an aluminum layer, and the passivation layer is a passivation layer of Al₂O₃.

According to embodiments of the present invention, the metal layer may have a thickness of 10-15 nm. According to embodiments of the present invention, the metal layer is an optically semi-transmissive layer and forms a micro resonant cavity together with the cathode layer.

According to embodiments of the present invention, an electron injection and transport layer is formed on the cathode layer before the step of forming the organic light-emitting layer. In some embodiments, the hole transport and injection layer has functions of both injection and transport of holes. In some other embodiments, the hole transport and injection layer may further comprise a hole injection sublayer and a hole transport sublayer.

According to embodiments of the present invention, a hole transport and injection layer is formed on the organic light-emitting layer before the step of forming the metal layer. In some embodiments, the hole transport and injection layer has functions of both injection and transport of holes. In some other embodiments, the hole transport and injection layer may further comprise a hole injection sublayer and a hole transport sublayer.

According to embodiments of the present invention, the cathode layer may be made of a lithium-aluminum alloy, and has a thickness of 200-300 nm

According to embodiments of the present invention, the anode layer may be made of indium tin oxide (ITO).

According to embodiments of the present invention, the organic light-emitting device is a top-emitting device.

Embodiments of the present invention provide a display comprising the above-mentioned organic light-emitting device.

### BRIEF DESCRIPTION OF THE DRAWINGS

FIG. 1 is a schematic structural view of an organic light-emitting device according to an embodiment of the present invention; and

FIG. 2 is a flow diagram of a method of manufacturing an organic light-emitting device according to an embodiment of the present invention.

### DETAILED DESCRIPTION OF THE EMBODIMENTS

Reference will now be made in detail to the specific embodiments of the present invention, examples of which are illustrated in the accompanying drawings, wherein like reference numerals refer to like elements throughout. The specific embodiments described below with reference to the accompany drawings are illustrative, are intended to explain the present invention, and should not be construed to limit the present invention.

The object, technical solutions and advantages of the present invention will be apparent and more readily appreciated from the following description of embodiments taken in conjunction with the accompanying drawings. In the accompanying drawings, 1 denotes a substrate, 2 denotes a cathode layer, 3 denotes an electron injection and transport layer, 4 denotes an organic light-emitting layer, 5 denotes a hole transport and injection layer, 6 denotes a metal layer, 7 denotes a passivation layer, and 8 denotes an anode layer.

According to a concept of the present invention, there is provided an organic light-emitting device into which a micro resonant cavity and an inverted structure are integrated, and a method of manufacturing the same.

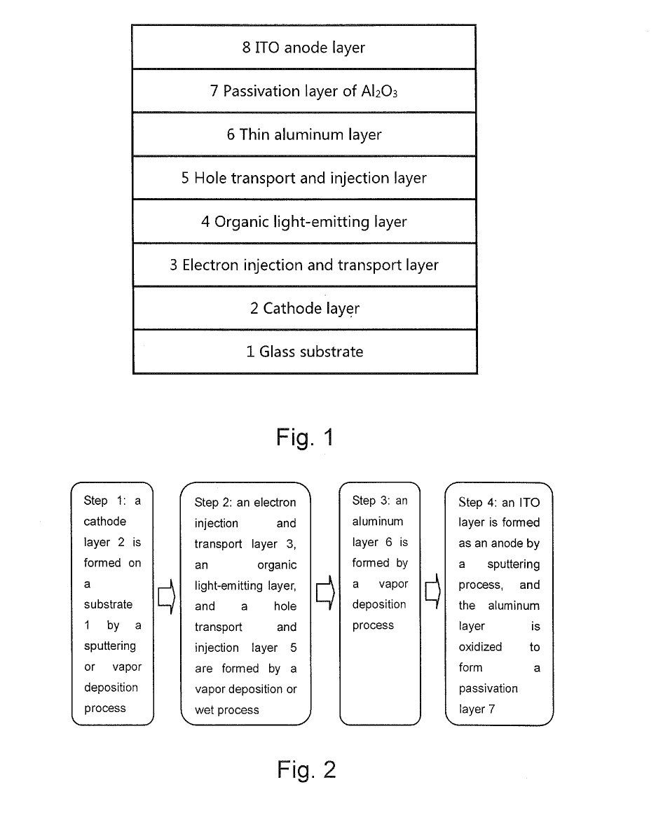

FIG. 1 is a schematic structural view of an organic light-emitting device according to an embodiment of the present invention. As shown in FIG. 1, the organic light-emitting device comprises a substrate 1, a cathode layer 2, an electron injection and transport layer 3, an organic light-emitting layer 4, a hole transport and injection layer 5, an aluminum layer 6, a passivation layer 7, and an anode layer 8 which are arranged from below upwards. The metal layer 6 is formed between the hole transport and injection layer 5 and the anode layer 8. Damage to the organic light-emitting layer 4 when the anode layer 8 is formed can be alleviated due to existence of the metal layer 6, while the anode layer 8 can also effectively prevent water and oxygen from corroding the organic light-emitting layer 4, thereby greatly prolonging the service life of the organic light-emitting device according to the embodiments of the present invention.

In an embodiment, the metal layer 6 is an optically semi-transmissive layer and forms a micro resonant cavity together with the cathode layer 2. Optically semi-transmissive property of the metal layer 6 is ensured by reducing the thickness of the metal layer 6. For example, the metal layer 6 may have a thickness of 10-15 nm. Since an inverted structure is combined with a micro resonant cavity design, intensity and color purity of light emitted by the organic light-emitting device are increased.

In an embodiment, the passivation layer 7 is formed by oxidizing a part of the metal layer 6 when the anode layer 8 is formed. According to embodiments of the present invention, the metal layer 6 is an aluminum layer, and accordingly the passivation layer 7 is a passivation layer of Al₂O₃. In addition, by forming the passivation layer 7 of Al₂O₃ between the hole transport and injection layer 5 and the anode layer 8, a potential barrier of injection and a turn-on voltage of the organic light-emitting device can be decreased, thereby reducing power consumption and protecting the organic layer.

In an embodiment of the present invention, the aluminum layer is formed by vapor deposition and may have a thickness of 10-15 nm. In this way, a thin aluminum layer having a particular thickness can be formed so as to ensure its optically semi-transmissive property. In addition, because of its small thickness, the aluminum layer will not adversely affect transport of holes.

In an embodiment of the present invention, the cathode layer 2 and the anode layer 8 are formed by a film forming process such as sputtering, vapor deposition, or the like. In an embodiment of the present invention, a top-emitting structure is adopted for the organic light-emitting device, and the cathode layer 2 may be made of a lithium-aluminum alloy having a low work function and may have a thickness of 200-300 nm, while the anode layer 8 may be made of indium tin oxide (ITO).

According to embodiments of the present invention, the electron injection and transport layer 3, the organic light-emitting layer 4, and the hole transport and injection layer 5 may be formed by a film forming process such as vapor deposition, a wet process, or the like. In addition, the electron injection and transport layer 3 in this embodiment may be an electron injection and transport layer having functions of both injection and transport of electrons, or may also further comprise an electron injection sublayer and an electron transport sublayer. Likewise, the hole transport and injection layer 5 in this embodiment may be a hole injection and transport layer having functions of both injection and transport of holes, or may also further comprise a hole injection sublayer and a hole transport sublayer. Therefore, the organic light-emitting device according to the embodiments of the present invention is also easily conformed to an existing mature ITO sputtering process.

According to embodiments of the present invention, the electron injection and transport layer 3 and the organic light-emitting layer 4 may be made of material having a low work function. Moreover, in order to facilitate injection of holes, the hole injection and transport layer 5 may be made of material having a high work function. In addition, in the present embodiment, the substrate 1 is a glass substrate.

In addition, the inverted organic light-emitting device according to the embodiments of the present invention may be a top-emitting inverted organic light-emitting device. However, if necessary, a reflection layer may be additionally disposed on the anode layer, thereby to achieve a design of a bottom-emitting organic light-emitting device.

According to embodiments of the present invention, with a structure of the abovementioned inverted organic light-emitting device, firstly, damage to the organic light-emitting layer 4 when the anode layer 8 is formed can be alleviated due to existence of the metal layer 6, while the anode layer 8 can also effectively prevent water and oxygen from corroding the organic light-emitting layer 4, thereby greatly prolonging the service life of the top-emitting inverted organic light-emitting device with the micro resonant cavity according to the embodiments of the present invention; secondly, by forming the passivation layer 7 by oxidizing a part of the aluminum layer 6 when the anode layer 8 is formed, a potential barrier of injection of holes and a turn-on voltage of the organic light-emitting device can be decreased; furthermore, since an inverted structure is combined with a micro resonant cavity design, intensity and color purity of light emitted by the organic light-emitting device are increased; and finally, the organic light-emitting device according to the embodiments of the present invention is also easily conformed to an existing mature ITO sputtering process.

Embodiments of the present invention also provide a method of manufacturing an organic light-emitting device comprising at least the following steps.

At step 1, a cathode layer 2 is formed on a substrate 1.

According to embodiments of the present invention, the substrate 1 is a glass substrate.

In an embodiment of the present invention, the cathode layer 2 is formed by a film forming process such as sputtering, vapor deposition, or the like.

In an embodiment of the present invention, the cathode layer 2 is made of a lithium-aluminum alloy having a low work function and has a thickness of 200-300 nm.

At step 2, an organic light-emitting layer 4 is formed on the cathode layer 2.

According to embodiments of the present invention, an electron injection and transport layer 3 is formed on the cathode layer 2 before the step of forming the organic light-emitting layer 4. In some embodiments, the electron injection and transport layer 3 has functions of both injection and transport of electrons. In some other embodiments, the electron injection and transport layer 3 may further comprise an electron injection sublayer and an electron transport sublayer.

According to embodiments of the present invention, a hole transport and injection layer 5 is formed on the organic light-emitting layer 4 before the step of forming a metal layer 6. In some embodiments, the hole transport and injection layer 5 has functions of both injection and transport of holes. In some other embodiments, the hole transport and injection layer 5 may further comprise a hole injection sublayer and a hole transport sublayer.

According to embodiments of the present invention, the electron injection and transport layer 3 and the organic light-emitting layer 4 are made of material having a low work function, and in order to facilitate injection of holes, the hole injection and transport layer 5 is made of material having a high work function.

In an embodiment of the present invention, the electron injection and transport layer 3 and the organic light-emitting layer 4 are formed by a film forming process such as vapor deposition, a wet process, or the like.

At step 3, the metal layer 6 is formed on the organic light-emitting layer 4 (or the hole transport and injection layer 5).

In this way, due to existence of the metal layer, not only a micro cavity effect can be created, but damage (for example, by sputtering) to the organic light-emitting layer 4 and the hole transport and injection layer 5 when the anode layer 8 is formed can also be alleviated.

According to embodiments of the present invention, the metal layer 6 is made of aluminum, and accordingly the passivation layer 7 is a passivation layer of Al₂O₃. Furthermore, the metal layer 6 is an optically semi-transmissive layer and forms a micro resonant cavity together with the cathode layer 2.

In an embodiment of the present invention, the metal layer is formed by vapor deposition, and has a thickness of 10-15 nm. In this way, a thin aluminum layer having a particular thickness can be formed.

At step 4, an anode layer 8 is formed on the metal layer 6.

In the step 4 of forming the anode layer 8, while the anode layer 8 is formed, a part of the metal layer 6 is oxidized to form a passivation layer 7. By forming the passivation layer 7 of Al₂O₃ between the hole transport and injection layer 5 and the anode layer 8, a potential barrier of injection can be decreased and the organic layer can be protected.

According to the embodiments of the present invention, with the abovementioned method of manufacturing the inverted organic light-emitting device, firstly, damage to the organic light-emitting layer 4 when the anode layer 8 is formed can be alleviated due to existence of the metal layer 6, while the anode layer 8 can also effectively prevent water and oxygen from corroding the organic light-emitting layer 4, thereby greatly prolonging the service life of the top-emitting inverted organic light-emitting device according to the embodiments of the present invention; secondly, by forming the passivation layer 7 by oxidizing a part of the aluminum layer 6 when the anode layer 8 is formed, a potential barrier of injection of holes and a turn-on voltage of the organic light-emitting device can be decreased; furthermore, since an inverted structure is combined with a micro resonant cavity design, intensity and color purity of light emitted by the organic light-emitting device are increased; and finally, the organic light-emitting device according to the embodiments of the present invention is also easily conformed to an existing mature ITO sputtering process.

In addition, embodiments of the present invention also provide a display comprising the above-mentioned inverted organic light-emitting device.

The abovementioned specific embodiments of the present invention only exemplarily illustrate principle and efficacy of the present invention and are not intended to limit the present invention. It will be understood by those skilled in the art that various changes and modifications may be made without departing from the spirit and scope of the invention.

1. An organic light-emitting device, comprising a substrate, a cathode layer, an organic light-emitting layer, and an anode layer which are arranged in sequence from below upwards, wherein:
the organic light-emitting device further comprises a metal layer formed between the organic light-emitting layer and the anode layer.

2. The organic light-emitting device of claim 1, further comprising:
a passivation layer between the metal layer and the anode layer, wherein the passivation layer is formed by oxidizing a part of the metal layer while the anode layer is formed.

3. The organic light-emitting device of claim 2, wherein:
the metal layer is an aluminum layer, and the passivation layer a passivation layer of Al₂O₃.

4. The organic light-emitting device of claim 1, wherein:
the metal layer has a thickness of 10-15 nm, and the metal layer is an optically semi-transmissive layer and forms a micro resonant cavity together with the cathode layer.

5. The organic light-emitting device of claim 1, wherein:
the cathode layer is made of a lithium-aluminum alloy, and has a thickness of 200-300 nm.

6. The organic light-emitting device of claim 1, wherein:
the organic light-emitting device is a top-emitting device.

7. The organic light-emitting device of claim 1, further comprising:
an electron injection and transport layer arranged between the cathode layer and the organic light-emitting layer.

8. The organic light-emitting device of claim 1, further comprising:
a hole transport and injection layer arranged between the organic light-emitting layer and the metal layer.

9. The organic light-emitting device of claim 1, wherein:
the anode layer is made of indium tin oxide.

10. A method of manufacturing an organic light-emitting device, comprising:
step 1 of forming a cathode layer on a substrate;
step 2 of forming an organic light-emitting layer on the cathode layer;
step 3 of forming a metal layer on the organic light-emitting layer; and
step 4 of forming an anode layer on the metal layer.

11. The method of claim 10, wherein:
in the step 4 of forming the anode layer (8), while the anode layer is formed, a part of the metal layer is oxidized to form a passivation layer.

12. The method of claim 11, wherein:
the metal layer is an aluminum layer, and the passivation layer a passivation layer of Al₂O₃.

13. The method of any one of claim 10, wherein:
the metal layer has a thickness of 10-15 nm, and the metal layer is an optically semi-transmissive layer and forms a micro resonant cavity together with the cathode layer.

14. The method of any one of claim 10, wherein:
the cathode layer is made of a lithium-aluminum alloy, and has a thickness of 200-300 nm.

15. The method of any one of claim 10, wherein:
the organic light-emitting device is a top-emitting device.

16. The method of any one of claim 10, wherein:
an electron injection and transport layer is formed on the cathode layer before the step of forming the organic light-emitting layer, wherein the electron injection and transport layer and the organic light-emitting layer are made of material having a low work function.

17. The method of any one of claim 10, wherein:
a hole transport and injection layer is formed on the organic light-emitting layer before the step of forming the metal layer, wherein:
the hole transport and injection layer is made of material having a high work function.

18. The method of any one of claim 10, wherein:
the anode layer is made of indium tin oxide.

19. A display, comprising the organic light-emitting device according to claim 1.
